(19) United States
(12) Patent Application Publication
(10) Pub. No.: US 2009/0046497 A1
(43) Pub. Date: Feb. 19, 2009

(54) System and method for reducing critical current or magnetic random access memory

(76) Inventors: Te-Ho Wu, Yunlin (TW); Alberto Canizo Cabrera, Yunlin (TW); Lin-Xiu Ye, Yunlin (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 12/285,858

(22) Filed: Oct. 15, 2008

Related U.S. Application Data
(62) Division of application No. 11/645,550, filed on Dec. 27, 2006.

(30) Foreign Application Priority Data
Mar. 20, 2006 (TW) 95109490

(51) Int. Cl. G11C 11/02

(52) U.S. Cl. 365/158

(57) ABSTRACT

A system and a method for reducing critical current of magnetic random access memory (MRAM) are disclosed. The magnetic device includes at least a pinned layer, a spacer layer and a free layer, and the material of the pinned layer and the free layer is perpendicularly anisotropic ferrimagnetic. The spacer layer is an insulator. By the modified Landau-Lifshitz-Gilbert equations, the varying trend of the critical current can be estimated.

### RELATED APPLICATIONS

This application is a Divisional/Continuation patent application of co-pending application Ser. No. 11/645,550, filed on 27 Dec. 2006. The entire disclosure of the prior application Ser. No. 11/645,550, from which an oath or declaration is supplied, is considered a part of the disclosure of the accompanying Divisional/Continuation application and is hereby incorporated by reference.

### BACKGROUND

1. Field of Invention

The present invention relates to a system and a method for reducing critical current of magnetic random access memory, and more particularly to a system and a method for reducing critical current of a magnetic device with perpendicularly anisotropic ferrimagnetic structure.

2. Description of Related Art

Most magnetic memory devices employ magneto resistance of in-the-plane magnetic elements for storing data. For example, Magnetic Random Access Memory (“MRAM”) is a kind of non-volatile memory utilized for data storage. MRAM devices offer low power consumption and high reliability. In addition, MRAM devices can have a higher density memory device array than other conventional storage devices.

Reference is made to FIG. 1a and FIG. 1b, which show a conventional magnetic memory device 100. The magnetic memory device 100 includes an antiferromagnetic layer 110, a pinned layer 120, a spacer layer 130 and a free layer 140.

The antiferromagnetic layer 110 is used to fix, or pin, the magnetization of the pinned layer 120 in a particular direction. The pinned layer 120 and the free layer 140 are ferromagnetic with a magnetization 121 and 141 in the plane, respectively. The spacer layer 130 is a nonmagnetic insulator. The magnetization 141 of the free layer 140 is free to rotate, typically in response to an external field.

FIG. 1a shows the magnetization 121 and 141 as parallel in the same direction. In this configuration, the magnetic resistance of the magnetic random access memory 100 is in a lower state. FIG. 1b shows the magnetization 121 and 141 as parallel in opposite directions, and the magnetic resistance of the magnetic random access memory 100 is in a higher state.

A conventional method for changing the direction of the magnetization of the free layer is to apply two orthogonal currents to the magnetic device, for example, the X-Y selection mechanism. The method applies two orthogonal currents as read and write currents of each magnetic device. Thus, either a definite volume of each magnetic device is required, or the adjacent magnetic device in the memory device array is affected by the read or write current.

However, there are some disadvantages in the conventional magnetic device. For example,

1. The conventional magnetic device needs an antiferromagnetic layer to fix the pinned layer's magnetization; the manufacturing process is more complicated.

2. The known method of changing the magnetization direction limits the density of the magnetic device array, thus raising power consumption.

### SUMMARY

It is therefore an objective of the present invention to provide a system that can be a magnetic random access memory, which applies perpendicularly anisotropic ferrimagnetic material to form the pinned layer and the free layer. There is no need for the additional antiferromagnetic layer of the prior art to fix the pinned layer. Unlike the prior art, the magnetization of the pinned layer and the free layer are perpendicularly anisotropic, so the volume of the magnetic device of the present invention can be smaller than the known one.

It is another objective of the present invention to provide a method for reducing critical current of the magnetic random access memory. The method employs a modified Landau-Lifshitz-Gilbert (LLG) equation that includes spin transfer effect to simulate the variation of critical current value.

According to the aforementioned objectives of the present invention, a magnetic system is provided. In one embodiment of the present invention, the magnetic system includes a pinned layer, a spacer layer and a free layer. The pinned layer is the base layer of the magnetic system, and the free layer is the top layer. The material of the pinned layer and the free layer are ferrimagnetic, and both of the magnetizations are perpendicularly anisotropic, wherein the magnetization of the free layer is free to rotate. The spacer layer is between the pinned layer and the free layer, and the material of the spacer layer is insulating material.

The magnetization precession and switching (i.e. rotation) of the free layer is induced by the spin transfer torque of spin-polarized current, and the positive/negative spin-polarized current passes through the magnetic system's sandwich structure, which means the electrons flow up or down.

In accordance with the foregoing and other objectives of the present invention, a method for reducing critical current is provided. A final equation via the modified LLG equation is obtained to describe the dynamics of net magnetization. The final equation shows the time evolution of net magnetization under the influence of a spin-polarized current, as well as the estimation of the critical current for the practical application in MRAM writing.

Because the different spin-polarized currents have distinct spin orientations, individual critical current and current density values are obtained. Finally, the varying trend of the critical current is given.

It is to be understood that both the foregoing general description and the following detailed description are by examples and are intended to provide further explanation of the invention as claimed.

### BRIEF DESCRIPTION OF THE DRAWINGS

The accompanying drawings are included to provide a further understanding of the invention and are incorporated in and constitute a part of this specification. The drawings illustrate embodiments of the invention and, together with the description, serve to explain the principles of the invention. In the drawings,

FIG. 1a illustrates a prior art magnetic device whose magnetizations are parallel;

FIG. 1b illustrates a prior art magnetic device whose magnetizations are antiparallel;

FIG. 2 illustrates a magnetic random access memory of the preferred embodiment of the present invention;

FIG. 3 illustrates a spin-polarized current applied to a magnetic system of the preferred embodiment of the present invention;

FIG. 4a illustrates the spin orientation of the spin-polarized current applied to the magnetic system (θ=0);

FIG. 4b illustrates the spin orientation of the spin-polarized current applied to the magnetic system (θ=π/2);

FIG. 4c illustrates the spin orientation of the spin-polarized current applied to the magnetic system (θ=π); and

FIG. 4d illustrates the spin orientation of the spin-polarized current applied to the magnetic system (θ=3π/2).

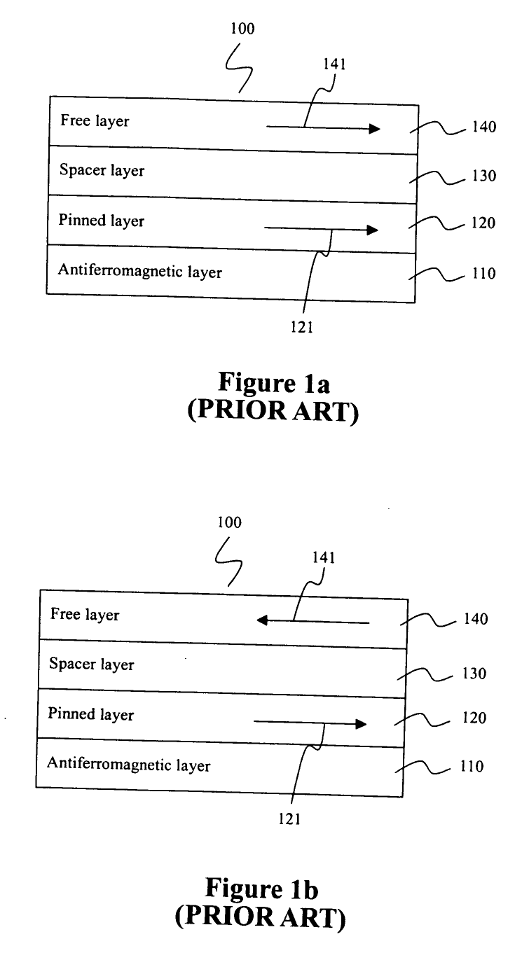

### DESCRIPTION OF THE PREFERRED EMBODIMENTS

Reference is now made in detail to the present preferred embodiments of the invention, examples of which are illustrated in the accompanying drawings. Wherever possible, the same reference numbers are used in the drawings and the description to refer to the same or like parts.

While the specification concludes with claims defining the features of the invention that are regarded as novel, it is believed that the invention is better understood from a consideration of the following description in conjunction with the figures, in which like reference numerals are carried forward.

### First Embodiment

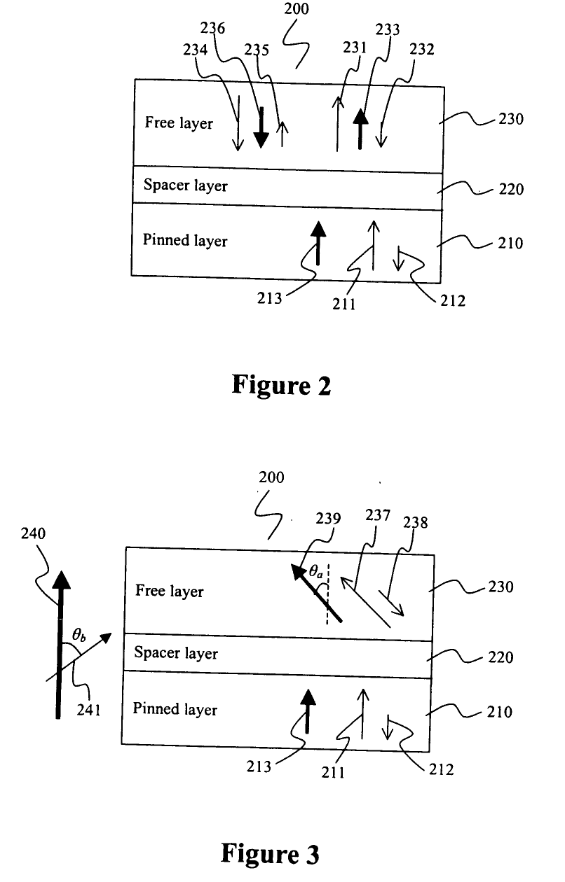

Reference is made to FIG. 2, which illustrates a magnetic memory random access memory of the preferred embodiment of the present invention. A magnetic random access memory 200 includes a pinned layer 210, a spacer layer 220 and a free layer 230.

The pinned layer 210 is a base layer of the magnetic random access memory 200. The material of the pinned layer 210 may be a ferrimagnetic thin film, such as TbFeCo alloy, DyFeCo alloy, Co/Pt multilayer thin film, Co/Pd multilayer thin film, or other ferrimagnetic multilayer thin film. A dipole moment 211 and a dipole moment 212 are perpendicularly anisotropic and represent a definite strength, form a net magnetization of first layer 213.

The spacer layer 220 is a nonmagnetic layer, which is an insulator. The free layer 230 is a top layer of the magnetic random access memory 200. The material of the free layer 230 could be a ferrimagnetic thin film, such as TbFeCo alloy, DyFeCo alloy, Co/Pt multilayer thin film, Co/Pd multilayer thin film, or other ferrimagnetic multilayer thin film. If the free layer 230 is a TM-rich (Transition Metal; TM) material, wherein a component of a magnetization 231 and a component of a magnetization 232 form a net magnetization of second layer 233; if the free layer 230 is a RE-rich (Rare Earth; RE) material, wherein a component of a magnetization 234 and a component of a magnetization 235 form a net magnetization of second layer 236, which are perpendicularly anisotropic and free to rotate; namely, the net magnetization of second layer 233 and the net magnetization of second layer 236 may form an included angle with the direction normal to the layers.

The thickness of the pinned layer 210 is 0.5 to 100 nm. The thickness of the spacer layer 220 is 0.5 to 10 nm. The thickness of the free layer 230 is 0.5 to 100 nm. The thickness and the composition of every layer can be modulated to change their magnetic and electric properties.

### Second Embodiment

Reference is made to FIG. 3, which illustrates a spin-polarized current applied to the magnetic memory device of the preferred embodiment of the present invention.

A component of a magnetization 237 and a component of a magnetization 238 of the free layer 230 form a net magnetization of second layer 239, and the net magnetization of second layer 239 may form an included angle θₐ with the direction normal to the layers, namely, the net magnetization of second layer 239 substantially perpendicular to the free layer 230.

A spin-polarized current 240 drives through the magnetic random access memory 200 upward or downward as a read current or a write current, which makes the net magnetization of second layer 239 turn upward or downward (i.e. the spin transfer effect). The orientation of spin 241 has an included angle θ_{b} with the spin-polarized current 240, which determines the critical current value.

### Third Embodiment

Referring to FIG. 3 again, modified LLG equations (1) and (2) for the net magnetization of second layer 239 formed by the component of a magnetization 237 and the component of a magnetization 238 are given below, by taking the parameters into account in Table 1:

TABLE 1

| | |
|---|---|
| | (1) |
| ${M}_{1} = {γ}_{1} {M}_{1} \times ( {H}_{1} + {hM}_{2} ) - {α}_{1} {M}_{1} \times {\dot{μ}}_{1} \pm \frac{{γ}_{1} ℏ}{eV} \frac{{I}_{e 1} {g}_{1}^{\pm }}{{M}_{1}} {M}_{1} \times {μ}_{1} \times {μ}_{3}$ | |
| | (2) |
| ${M}_{2} = {γ}_{2} {M}_{2} \times ( {H}_{2} + {hM}_{1} ) - {α}_{2} {M}_{2} \times {\dot{μ}}_{2} \pm \frac{{γ}_{2} ℏ}{eV} \frac{{I}_{e 2} {g}_{2}^{\pm }}{{M}_{2}} {M}_{2} \times {μ}_{2} \times {μ}_{3}$ | |

| Parameters | Definitions of the parameters |
|---|---|
| M₁ | component of a magnetization 237 |
| M₂ | component of a magnetization 238 |
| M₁ | magnetization magnitude of M₁ |
| M₂ | magnetization magnitude of M₂ |
| γ₁ | gyromagnetic ratio of the component of a magnetization |
| | 237 |
| γ₂ | gyromagnetic ratio of the component of a magnetization |
| | 238 |
| H₁ | net effective field of the component of a magnetization 237 |
| H₂ | net effective field of the component of a magnetization 238 |
| hM₁ | effective local exchange field of the component of a |
| | magnetization 237 on the component of a magnetization |
| | 238 (where h ≦ 0) |
| hM₂ | effective local exchange field of the component of a |
| | magnetization 238 on the component of a magnetization |
| | 237 (where h ≦ 0) |
| α₁ | corresponding damping coefficient of γ₁ |
| α₂ | corresponding damping coefficient of γ₂ |
| μ₁ | unit vector of M₁ |
| μ₂ | unit vector of M₂ |
| μ₃ | unit vector of the net magnetization of first layer 213 |
| | reduced Planck's constant = h/2π |
| e | electron charge = 1.602 × 10⁻¹⁹ Coulomb |
| V | volume of the free layer 230 |
| Iₑ₁ | spin-polarized current of electron 1 (e1) |
| Iₑ₂ | spin-polarized current of electron 2 (e2) |
| g₁ | coefficient for the component of a magnetization 237 which |
| | depends on polarization of the electron 1 (e1) |
| g₂ | coefficient for the component of a magnetization 238 which |
| | depends on polarization of the electron 2 (e2) |
| ± | positive or negative, depending on the direction of the |
| | spin-polarized current |

From modified LLG equations (1) and (2) above, an intermediate formula (3) can be obtained for strongly coupled multilayer ferrimagnets below, wherein the “eff” index of the formulas (3), (4), (5), (6) and (7) means the net effective value of each parameter:

$$\begin{matrix}\dot{μ} = {γ}_{eff} μ \times {H}_{eff} - {α}_{eff} μ \times \dot{μ} \pm {a}_{l eff}^{\pm } μ \times μ \times {μ}_{3} & ( 3 ) \\ {γ}_{eff} = \frac{{M}_{1} - {M}_{2}}{{M}_{1} / {γ}_{1} - {M}_{2} / {γ}_{2}} & ( 4 ) \\ {α}_{eff} = \frac{{α}_{1} {M}_{1} / {γ}_{1} + {α}_{2} {M}_{2} / {γ}_{2}}{{M}_{1} / {γ}_{1} - {M}_{2} / {γ}_{2}} & ( 5 ) \\ {a}_{l eff}^{\pm } = \frac{ℏ}{eV} \frac{( {I}_{e 1} {g}_{1}^{\pm } + {I}_{e 2} {g}_{2}^{\pm } )}{( {M}_{1} / {γ}_{1} - {M}_{2} / {γ}_{2} )} & ( 6 ) \\ {H}_{eff} = \frac{{M}_{1} {H}_{1} - {M}_{2} {H}_{2}}{{M}_{1} - {M}_{2}} & ( 7 ) \\ {I}_{e 1 , 2} = I + 2 I ( 1 + cos {θ}_{1 , 2} ) / ( 3 + cos {θ}_{1 , 2} ) & ( 8 )\end{matrix}$$

The θ_{1,2} of the formula (8) depends on the orientation of the spin 241 with regard to orientation of the net magnetization of second layer 239 formed by the component of a magnetization 237 and the component of a magnetization 238.

Assuming μ₃=c, H_{eff}=H_{eff} c (C is a constant), and considering an antiparallel coupling effect between magnetic rare-earth (RE) and transition-metal (TM) samples, the aforementioned intermediate formula (3) can be solved as follows:

\dot{θ}=±(a_{I}_{_{eff}}^{±}−ωα_{eff})sin θ (9)

A resultant formula (9) allows obtaining the eight critical current values of the spin-polarized current for different spin orientations, which present in the form of the formulas (10), (11) and (12) below:

$$\begin{matrix}{I}_{C}^{\pm , a} = \frac{{α}_{eff} ω eV ( {M}_{1} / {γ}_{1} + {M}_{2} / {γ}_{2} )}{( 2 {g}_{1}^{\pm } + {g}_{2}^{\pm } ) ℏ} & ( 10 ) \\ {I}_{C}^{\pm , b , d} = \frac{3}{5} \frac{{α}_{eff} ω eV ( {M}_{1} / {γ}_{1} + {M}_{2} / {γ}_{2} )}{( {g}_{1}^{\pm } + {g}_{2}^{\pm } ) ℏ} & ( 11 ) \\ {I}_{C}^{\pm , c} = \frac{{α}_{eff} ω eV ( {M}_{1} / {γ}_{1} + {M}_{2} / {γ}_{2} )}{( {g}_{1}^{\pm } + 2 {g}_{2}^{\pm } ) ℏ} & ( 12 )\end{matrix}$$

### Fourth Embodiment

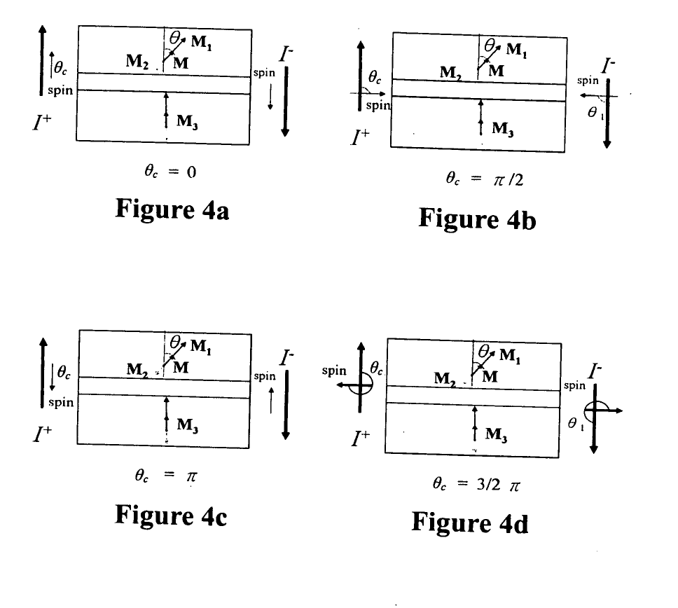

Reference is made to FIGS. 4a, 4b, 4c and 4d, wherein there are eight spin orientation configurations of the spin-polarized current applied to the same magnetic memory device. The component of a magnetization and the net magnetization of the free layer may have a included angle θ with the perpendicular line and free to rotate.

For example, a Tbₓ(FeCo)₁₋ₓ sample using M₁=2644 X_{R} emu/cm³ and M₂=799(1−X_{R}) emu/cm³, where X_{R} is atomic percentage of the RE element, a minimum value for both I_{c}⁺ and I_{c}⁻ when X_{R}=24% can be found.

The I_{c}^{+,i} and I_{c}^{-,i} values are obtained (the result listed in Table 2 below) by using formulas (10), (11) and (12), which assume a 60×130 nm² elliptical sample for a Tbₓ(FeCo)₁₋ₓ ferrimagnetic structure. The parameters used in all the results mentioned are in Table 3 below.

As the value of the spin orientation θ_{c} changes from 0 to π, the value of critical current Ic⁻ decreases; and the current density Jc⁺ also decreases. Furthermore, when the value of the spin orientation θ_{c} changes from π to 0, the value of critical current Ic⁻ decreases; and the current density Jc⁺ also decreases continuously.

TABLE 2

| Spin | | | | |
|---|---|---|---|---|
| orientation | Ic⁺ | Jc⁺ | Ic⁻ | Jc⁻ |
| (θ_{c}) | (μA) | (A/cm²) | (μA) | (A/cm²) |
| 0 | 482.09 | 1.97 × 10⁶ | −101.16 | −4.13 × 10⁵ |
| π/2 | 302.20 | 1.23 × 10⁶ | −120.37 | −4.91 × 10⁵ |
| π | 257.59 | 1.05 × 10⁶ | −197.27 | −8.05 × 10⁵ |
| 3π/2 | 302.2 | 1.23 × 10⁶ | −120.37 | −4.91 × 10⁵ |

TABLE 3

| | Rare-Earth | Transition Metal |
|---|---|---|
| M (emu/cm³) | 634.56 | 607.24 |
| γ (Hz/Oe) | γ₁ = 1.0 × 10⁷ | γ₂ = 2.5 × 10⁷ |
| α (damping coefficient) | α₁ = 0.25 | α₂ = 0.5 |
| Ku (erg/cm³) | Ku₁ = 1.5 × 10⁵ | Ku₂ = 1.0 × 10⁵ |
| P (the polarizing factor) | 0.8 | 0.7 |

By the manner of deriving the modified LLG equations, the variation tendency of the critical current value can be confirmed by changing the spin orientation. After setting some boundary conditions, the estimation of the critical current is obtained.

According to the composition and the embodiments above, there are many advantages of the present invention over the prior art, such as:

1. The manufacturing processes and the structural layers of the magnetic system of the present invention are fewer than those of the prior art, so the cost and yield of production are improved.

2. The material of the pinned layer and the free layer is perpendicularly anisotropic ferrimagnetic, which allows the volume of a single magnetic system to be smaller than that of the prior art.

3. By the method of controlling the spin orientation of the spin-polarized current, the power consumption of the magnetic system can be reduced via reducing critical current.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method for reducing critical current of a magnetic random access memory, comprising:
using modified Landau-Lifshitz-Gilbert equations to derive an intermediate formula describes the dynamics of net magnetization;
calculating the dynamics of net magnetization by the intermediate formula under the influence of a spin-polarized current to derive a resultant formula, wherein the spin-polarized current is arranged to apply to the magnetic random access memory; and
inputting the boundary conditions of the magnetic random access memory into the resultant formula to obtain a value of the critical current.

2. The method of claim 1, wherein the modification of the modified Landau-Lifshitz-Gilbert equations is provided by involving effective parameters.

3. The method of claim 1, wherein a value of the critical current is decreased by changing a spin orientation of the spin-polarized current.
